(19) United States
(12) Patent Application Publication
(10) Pub. No.: US 2025/0169096 A1
(43) Pub. Date: May 22, 2025

(54) SEMICONDUCTOR DEVICE

(71) Applicant: SAMSUNG ELECTRONICS CO., LTD., Suwon-si (KR)

(72) Inventors: Sangjun LEE, Suwon-si (KR); Boram KIM, Suwon-si (KR); JONGSEOB KIM, Suwon-si (KR); JONGUK SEO, Suwon-si (KR); JUNGSEUNG YANG, Suwon-si (KR); JAEJOON OH, Suwon-si (KR); YONGSEOK CHOI, Suwon-si (KR)

(73) Assignee: SAMSUNG ELECTRONICS CO., LTD., Suwon-si (KR)

(21) Appl. No.: 18/671,507

(22) Filed: May 22, 2024

(30) Foreign Application Priority Data
Nov. 20, 2023 (KR) 10-2023-0161055

(51) Int. Cl. H01L 29/778; H01L 29/20; H01L 29/423; H01L 29/66

(52) U.S. Cl. CPC H10D 30/475; H10D 30/015; H10D 30/4732; H10D 62/8503; H10D 64/411

(57) ABSTRACT

A semiconductor device according to an embodiment includes: a channel layer; a barrier layer above the channel layer and including a material having an energy band gap different from an energy band gap of the channel layer; a gate electrode above the barrier layer; a gate semiconductor layer between the barrier layer and the gate electrode; a source electrode and a drain electrode that are at both sides of the gate electrode and covering side surfaces of the channel layer and the barrier layer; and a superlattice layer between the barrier layer and the gate semiconductor layer, the superlattice layer including at least one first layer including AlGaN and at least one second layer including GaN, wherein the at least one first layer and the at least one second layer are alternately stacked.

### CROSS-REFERENCE TO RELATED APPLICATION

This application claims priority to and the benefit of Korean Patent Application No. 10-2023-0161055, filed at the Korean Intellectual Property Office on Nov. 20, 2023, the entire contents of which are incorporated herein by reference.

### BACKGROUND

### 1. Field

Embodiments of the present disclosure relate to a semiconductor device.

### 2. Description of Related Art

In modern society, a semiconductor device is closely related to daily life. In particular, importance of an electric power semiconductor device used in various fields such as a transportation field including electric vehicles, railways, electric trams, or the like, a renewable energy system such as solar power generation, wind power generation, or the like, a mobile device, and the like is gradually increasing. An electric power semiconductor device is a semiconductor device used to handle a high voltage or a high current, and performs functions such as electric power conversion, control, the like in a large electric power system or a high-power electronic device. The electric power semiconductor device may have an ability to handle high electric power and durability, so that it may handle a large amount of current and may withstand a high voltage. For example, the electric power semiconductor device may handle a voltage ranging from hundreds of volts to thousands of volts and a current ranging from tens of amperes to thousands of amperes. The electric power semiconductor device may improve efficiency of electrical energy by minimizing electric power loss. Additionally, the electric power semiconductor device may be stably driven even in an environment including a high temperature or the like.

The electric power semiconductor device may be classified according to a material and, for example, it may include a SiC electric power semiconductor device and a GaN electric power semiconductor device. The electric power semiconductor device may be manufactured using SiC or GaN instead of an existing silicon (Si) wafer, so that a drawback of silicon that has an unstable characteristic at a high temperature may be compensated. The SiC electric power semiconductor device may be resistant to a high temperature, may have low power loss, and may be suitable for the electric vehicle, the renewable energy system, or the like. The GaN electric power semiconductor device may require a high cost, but it may be efficient in terms of speed and may be suitable for high-speed charging or the like of the mobile device.

### SUMMARY

According to embodiments of the present disclosure, a semiconductor device with an improved electric characteristic and reliability is provided.

According to embodiments of the present disclosure, a semiconductor device is provided and includes: a channel layer; a barrier layer above the channel layer and including a material having an energy band gap that is different from an energy band gap of the channel layer; a gate electrode above the barrier layer; a gate semiconductor layer between the barrier layer and the gate electrode; a source electrode at a first side of the gate electrode and on a first side surface of the channel layer and a first side surface of the barrier layer; a drain electrode at a second side of the gate electrode, opposite to the first side, and on a second side surface of the channel layer and a second side surface of the barrier layer; and a superlattice layer between the barrier layer and the gate semiconductor layer, the superlattice layer including at least one first layer including AlGaN and at least one second layer including GaN, wherein the at least one first layer and the at least one second layer are alternately stacked.

According to embodiments of the present disclosure, a semiconductor device is provided and includes: a substrate; a buffer layer on the substrate; a lower superlattice layer above the buffer layer; a channel layer above the lower superlattice layer; a barrier layer above the channel layer and including a material with an energy band gap that is higher than an energy band gap of the channel layer; a spacer layer between the channel layer and the barrier layer and including a material with an energy band gap that is higher than the energy band gap of the barrier layer; a gate electrode above the barrier layer; a gate semiconductor layer between the barrier layer and the gate electrode; a source electrode at a first side of the gate electrode and on a first side surface of the channel layer and a first side surface of the barrier layer; a drain electrode at a second side of the gate electrode, opposite to the first side, and on a second side surface of the channel layer and a second side surface of the barrier layer; and an upper superlattice layer between the barrier layer and the gate semiconductor layer, the upper superlattice layer including at least one first layer including AlGaN and at least one second layer including GaN, wherein the at least one first layer and the at least one second layer are alternately stacked.

According to embodiments of the present disclosure, a semiconductor device is provided and includes: a channel layer including GaN; a barrier layer above the channel layer and including AlGaN; a gate electrode above the barrier layer and including a metallic material; a gate semiconductor layer between the barrier layer and the gate electrode and including GaN doped with p-type impurities; a source electrode at a first side of the gate electrode and in contact with a first side surface of the channel layer and a first side surface of the barrier layer; a drain electrode at a second side of the gate electrode, opposite to the first side, and in contact with a second side surface of the channel layer and a second side surface of the barrier layer; and a superlattice layer between the barrier layer and the gate semiconductor layer, the superlattice layer including at least one first layer including AlGaN and at least one second layer including GaN, wherein the at least one first layer and the at least one second layer are alternately stacked.

According to embodiments of the present disclosure, a threshold voltage of a semiconductor device may be increased while minimizing a defect inside a film by improving doping efficiency, so that the semiconductor device with an improved electric characteristic and reliability may be provided.

### BRIEF DESCRIPTION OF DRAWINGS

FIG. 1 is a cross-sectional view showing a semiconductor device according to an embodiment.

FIG. 2 is a cross-sectional view showing the semiconductor device according to the embodiment.

FIG. 3 is an enlarged cross-sectional view of a region A of FIG. 1.

FIG. 4 is a view for describing a threshold voltage of the semiconductor device according to a composition ratio of aluminum inside a superlattice layer.

FIG. 5 is a view showing a semiconductor device according to an embodiment.

FIG. 6 is a view showing a semiconductor device according to an embodiment.

FIGS. 7 to 12 are process cross-sectional views showing a process sequence for manufacturing a semiconductor device according to an embodiment.

### DETAILED DESCRIPTION

Below, non-limiting example embodiments of the present disclosure will be described with reference to accompanying drawings to such an extent as to be easily realized by a person having ordinary skill in the art in the technical field pertaining to the present disclosure. Embodiments of the present disclosure may be modified in various different ways, all without departing from the spirit or scope of the present disclosure.

In order to clearly describe embodiments of the present disclosure, parts or portions that are irrelevant to the description may be omitted, and identical or similar constituent elements throughout the specification are denoted by the same reference numerals.

Further, in the drawings, the size and thickness of each element may be arbitrarily illustrated for ease of description, and embodiments of the present disclosure are not necessarily limited to the embodiments illustrated in the drawings. In the drawings, the thicknesses of layers, films, panels, regions, areas, etc., may be exaggerated for clarity.

It will be understood that when an element such as a layer, film, region, area, or substrate is referred to as being “on” or “above” another element, it may be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” (and “include”) and variations such as “comprises” or “comprising” (and “includes” or “including”) will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

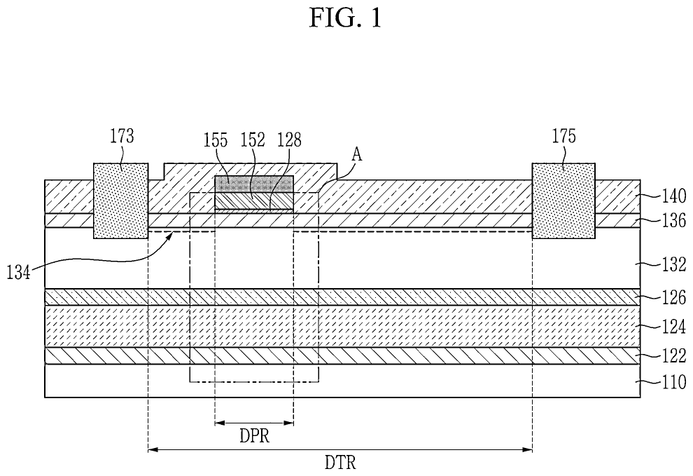

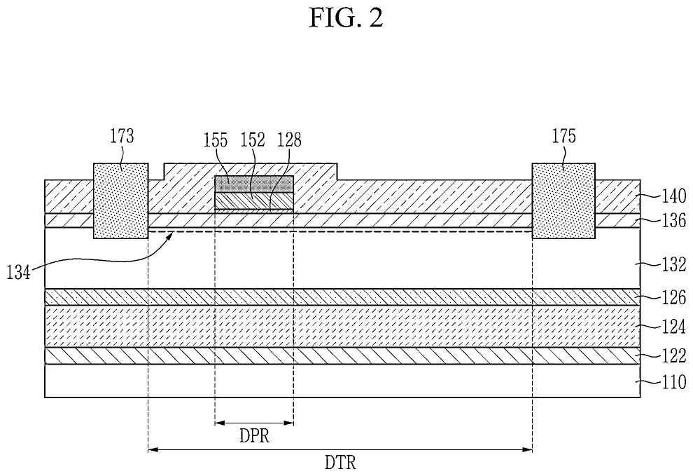

Hereinafter, a semiconductor device according to an embodiment will be described with reference to FIG. 1 and FIG. 2.

FIG. 1 and FIG. 2 are cross-sectional views showing a semiconductor device according to an embodiment. FIG. 1 shows a case where the semiconductor device according to the embodiment is in an off state, and FIG. 2 shows a case where the semiconductor device according to the embodiment is in an on state.

As shown in FIG. 1, the semiconductor device according to the embodiment may include a channel layer 132, a barrier layer 136 disposed on the channel layer 132, a gate electrode 155 disposed above the barrier layer 136, a gate semiconductor layer 152 disposed between the barrier layer 136 and the gate electrode 155, a source electrode 173 and a drain electrode 175 spaced apart from each other on the channel layer 132, and an upper superlattice layer 128 disposed between the barrier layer 136 and the gate semiconductor layer 152.

The channel layer 132 may be a layer that forms a channel between the source electrode 173 and the drain electrode 175, and a two-dimensional electron gas (2DEG) 134 may be disposed inside the channel layer 132. The two-dimensional electron gas 134 may be a charge transport model used in solid state physics, and may refer to a group of electrons that may freely move in two dimensions (e.g., an x-y plane direction), may not move in another dimension (e.g., in a z direction vertical to the x-y plane direction), and may be tightly confined within the two dimensions. In other words, the two-dimensional electron gas 134 may exist in a form of a two-dimensional paper within a three-dimensional space. The two-dimensional electron gas 134 may mainly appear in a semiconductor heterojunction structure, and may occur at an interface between the channel layer 132 and the barrier layer 136 in the semiconductor device according to the embodiment. For example, the two-dimensional electron gas 134 may be generated at a portion adjacent to the barrier layer 136 within the channel layer 132.

For example, the channel layer 132 may include at least one material selected from nitride including at least one from among Group III-V materials (e.g., Al, Ga, In, and B). The channel layer 132 may be formed of a single layer or multiple layers. The channel layer 132 may be AlₓIn_{y}Ga_{1-x-y}N (0≤x≤1, 0≤y≤1, and x+y≤1). For example, the channel layer 132 may include at least one from among AlN, GaN, InN, InGaN, AlGaN, AlInN, and AlInGaN. The channel layer 132 may be a layer doped with impurities or a layer undoped with an impurity. A thickness of the channel layer 132 may be about several hundred nm or less.

The channel layer 132 may be disposed above a substrate 110, and a buffer layer 122, a lower superlattice layer 124, a high resistance layer 126, and the like may be disposed between the substrate 110 and the channel layer 132. The substrate 110, the buffer layer 122, and the lower superlattice layer 124 may be layers for forming the channel layer 132, and may be omitted in an embodiment. For example, if a substrate made of GaN is used as the channel layer 132, at least one from among the substrate 110, the buffer layer 122, and the lower superlattice layer 124 may be omitted. Considering that a cost of the substrate made of GaN is relatively high, the channel layer 132 including GaN may be grown using the substrate 110 made of Si. In this case, because a lattice structure of Si and a lattice structure of GaN are different, it may not be easy to grow the channel layer 132 directly on the substrate 110. Accordingly, the buffer layer 122 and the lower superlattice layer 124 may be first grown on the substrate 110, and then the channel layer 132 may be grown above the lower superlattice layer 124. Additionally, at least one from among the substrate 110, the buffer layer 122, and the lower superlattice layer 124 may be removed from a final structure of the semiconductor device after it is used in a manufacturing process.

The substrate 110 may include a semiconductor material. For example, the substrate 110 may include sapphire, Si, SiC, AlN, GaN, or a combination thereof. The substrate 110 may be a silicon-on-insulator (SOI) substrate. However, a material of the substrate 110 is not limited thereto, and all commonly used substrates may be applied to the substrate 110. In an embodiment, the substrate 110 may include an insulating material. For example, several layers including the channel layer 132 may be first formed on the semiconductor substrate, and then the semiconductor substrate may be removed and may be replaced with the insulating substrate.

The buffer layer 122 may be disposed on the substrate 110. According to embodiments, a seed layer may be further disposed between the substrate 110 and the buffer layer 122. The seed layer may be disposed directly on the substrate 110. However, embodiments of the present disclosure are not limited thereto, and another predetermined layer may be further disposed between the substrate 110 and the seed layer. The seed layer may be a layer that serves as a seed for growing the buffer layer 122, and may be formed of a crystal lattice structure that becomes the seed of the buffer layer 122. The buffer layer 122 may be disposed directly on the seed layer. However, embodiments of the present disclosure are not limited thereto, and another predetermined layer may be disposed between the seed layer and buffer layer 122.

The buffer layer 122 may be disposed between the substrate 110 and the lower superlattice layer 124. The buffer layer 122 may be a layer for alleviating a difference in a lattice constant and a thermal expansion coefficient between the substrate 110 and the channel layer 132. For example, the buffer layer 122 may include at least one material selected from nitride including at least one from among Group III-V materials (e.g., Al, Ga, In, and B). The buffer layer 122 may be AlₓIn_{y}Ga_{1-x-y}N (0≤x≤1, 0≤y≤1, x+y≤1). For example, the buffer layer 122 may include at least one from among AlN, GaN, InN, InGaN, AlGaN, AlInN, and AlInGaN. The buffer layer 122 may be formed of a single layer or multiple layers.

The lower superlattice layer 124 may be disposed above the buffer layer 122. The lower superlattice layer 124 may be disposed directly on the buffer layer 122. However, embodiments of the present disclosure are not limited thereto, and another predetermined layer may be further disposed between the buffer layer 122 and the lower superlattice layer 124. The lower superlattice layer 124 may be disposed between the buffer layer 122 and the channel layer 132. Like the buffer layer 122, the lower superlattice layer 124 may be a layer for alleviating a difference in a lattice constant and a thermal expansion coefficient between the substrate 110 and the channel layer 132. For example, the lower superlattice layer 124 may include at least one material selected from nitride including at least one from among Group III-V materials (e.g., Al, Ga, In, and B). The lower superlattice layer 124 may be AlₓIn_{y}Ga_{1-x-y}N (0≤x≤1, 0≤y≤1, and x+y≤1). For example, the lower superlattice layer 124 may include at least one from among AlN, GaN, InN, InGaN, AlGaN, AlInN, and AlInGaN. The lower superlattice layer 124 may be formed of a single layer or multiple layers. For example, the lower superlattice layer 124 may have a structure in which a layer made of AlGaN and a layer made of GaN are repeatedly stacked. For example, AlGaN/GaN/AlGaN/GaN/AlGaN/GaN may be sequentially stacked on the buffer layer 122 to form the lower superlattice layer 124. The number of AlGaN layers and GaN layers constituting the lower superlattice layer 124 may be variously changed, and a material constituting the lower superlattice layer 124 may be variously changed. As another embodiment, the lower superlattice layer 124 may have a structure in which a layer made of AlN and a layer made of AlGaN are repeatedly stacked. For example, AlN/AlGaN/AlN/AlGaN/AlN/AlGaN may be sequentially stacked on the buffer layer 122 to form the lower superlattice layer 124. In an embodiment, unlike the upper superlattice layer 128 described later, the lower superlattice layer 124 may not be doped with an impurity. However, embodiments of the present disclosure are not limited thereto, and the lower superlattice layer 124 may be doped with impurities.

The high resistance layer 126 may be disposed above the lower superlattice layer 124. The high resistance layer 126 may be disposed directly on the lower superlattice layer 124. However, embodiments of the present disclosure are not limited thereto, and another predetermined layer may be further disposed between the lower superlattice layer 124 and the high resistance layer 126. The high resistance layer 126 may be disposed between the lower superlattice layer 124 and the channel layer 132. The high resistance layer 126 may be intended to prevent the semiconductor device according to the embodiment including the channel layer 132 from being influenced by the outside. The high resistance layer 126 may be made of a material with low conductivity so that the substrate 110 and the channel layer 132 are electrically insulated from each other. For example, the high resistance layer 126 may include at least one material selected from nitride including at least one from among Group III-V materials (e.g., Al, Ga, In, and B). The high resistance layer 126 may be AlₓIn_{y}Ga_{1-x-y}N (0≤x≤1, 0≤y≤1, and x+y≤1). For example, the high resistance layer 126 may include at least one from among AlN, GaN, InN, InGaN, AlGaN, AlInN, and AlInGaN. The high resistance layer 126 may be formed of a single layer or multiple layers. The high resistance layer 126 may be a layer in which an impurity is not doped.

The barrier layer 136 may be disposed above the channel layer 132. The barrier layer 136 may be disposed directly on the channel layer 132. However, embodiments of the present disclosure are not limited thereto, and another predetermined layer may be further disposed between the channel layer 132 and the barrier layer 136. A region of the channel layer 132 that overlaps with the barrier layer 136 may be a drift region DTR. The drift region DTR may be disposed between the source electrode 173 and the drain electrode 175. If a potential difference occurs between the source electrode 173 and the drain electrode 175, a carrier may move in the drift region DTR. The semiconductor device according to the embodiment may be turned on/off depending on whether a voltage is applied to the gate electrode 155 and a size of a voltage applied to the gate electrode 155, and accordingly, the carrier may be moved or blocked in the drift region DTR.

For example, the barrier layer 136 may include at least one material selected from nitride including at least one from among Group III-V materials (e.g., Al, Ga, In, and B). The barrier layer 136 may be AlₓIn_{y}Ga_{1-x-y}N (0≤x≤1, 0≤y≤1, and x+y≤1). The barrier layer 136 may include at least one from among GaN, InN, AlGaN, AlInN, InGaN, AlN, AlInGaN, and the like. An energy band gap of the barrier layer 136 may be adjusted by a composition ratio (or a composition percent) of Al and/or In. The barrier layer 136 may be doped with predetermined impurities. In this case, the impurities doped into the barrier layer 136 may be p-type dopants capable of providing a hole. For example, the impurities doped in the barrier layer 136 may be magnesium (Mg). A threshold voltage, an on-resistance, or the like of the semiconductor device according to the embodiment may be adjusted by increasing or decreasing an impurity doping concentration of the barrier layer 136.

The barrier layer 136 may include a semiconductor material with a characteristic different from a characteristic of the channel layer 132. The barrier layer 136 may differ from the channel layer 132 in at least one of a polarization characteristic, an energy band gap, and a lattice constant. For example, the barrier layer 136 may include a material having a different energy band gap from that of the channel layer 132. In this case, the barrier layer 136 may have a higher energy band gap than that of the channel layer 132, and may have a higher electrical polarization rate than that of the channel layer 132. The two-dimensional electron gas 134 may be induced in the channel layer 132 having a relatively low electrical polarization rate by the barrier layer 136. In this regard, the barrier layer 136 may be referred to as a channel supply layer or a two-dimensional electron gas supply layer. The two-dimensional electron gas 134 may be formed within a portion of the channel layer 132 disposed below the interface between the channel layer 132 and the barrier layer 136. The two-dimensional electron gas 134 may have very high electron mobility.

The barrier layer 136 may be formed of a single layer or multiple layers. If the barrier layer 136 is formed of the multiple layers, materials of layers constituting the multiple layers may have different energy band gaps. In this case, the various layers constituting the barrier layer 136 may be disposed so that the energy band gap increases as they approach the channel layer 132.

The gate electrode 155 may be disposed above the barrier layer 136. The gate electrode 155 may overlap some regions of the barrier layer 136. The gate electrode 155 may overlap a portion of the drift region DTR of the channel layer 132. The gate electrode 155 may be disposed between the source electrode 173 and the drain electrode 175. The gate electrode 155 may be spaced apart from the source electrode 173 and the drain electrode 175.

In an embodiment, the barrier layer 136 may include an AlGaN layer. In this case, an Al composition ratio (or an Al composition percent) of the AlGaN layer included in the barrier layer 136 may be different from an Al composition ratio of an AlGaN layer included in the upper superlattice layer 128 that will be described later. The Al composition ratio may be an atomic percent of Al included in the AlGaN layer. In an embodiment, the Al composition ratio of the AlGaN layer included in the barrier layer 136 may be smaller than the Al composition ratio of the AlGaN layer included in the upper superlattice layer 128. For example, in the AlGaN layer included in the barrier layer 136, the Al composition ratio may be about 10 at % to about 20 at %. In an embodiment, the Al composition ratio of the AlGaN layer included in the upper superlattice layer 128 may be less than 10 at %.

The gate electrode 155 may include a conductive material. For example, the gate electrode 155 may include a metal, a metal alloy, conductive metal nitride, metal silicide, a doped semiconductor material, conductive metal oxide, conductive metal oxynitride, or the like. For example, the gate electrode 155 may include titanium nitride (TIN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TIC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or a combination thereof, but embodiments of the present disclosure are not limited thereto. The gate electrode 155 may be formed of a single layer or multiple layers.

The gate semiconductor layer 152 may be disposed between the barrier layer 136 and the gate electrode 155. That is, the gate semiconductor layer 152 may be disposed above the barrier layer 136, and the gate electrode 155 may be disposed on the gate semiconductor layer 152. The gate electrode 155 may be in an ohmic contact with the gate semiconductor layer 152. The gate semiconductor layer 152 may overlap with the gate electrode 155. In this case, the gate semiconductor layer 152 may completely overlap with the gate electrode 155 in a vertical direction, and an upper portion surface of the gate semiconductor layer 152 may be entirely covered by the gate electrode 155. That is, the gate semiconductor layer 152 may have substantially the same planar shape as that of the gate electrode 155.

The gate semiconductor layer 152 may be disposed between the source electrode 173 and the drain electrode 175. The gate semiconductor layer 152 may be spaced apart from the source electrode 173 and the drain electrode 175. The gate semiconductor layer 152 may be disposed closer to the source electrode 173 than the drain electrode 175. That is, a separation distance between the gate semiconductor layer 152 and the source electrode 173 may be smaller than a separation distance between the gate semiconductor layer 152 and the drain electrode 175.

For example, the gate semiconductor layer 152 may include at least one material selected from nitride including at least one from among Group III-V materials (e.g., Al, Ga, In, and B). The gate semiconductor layer 152 may be AlₓIn_{y}Ga_{1-x-y}N (0≤x≤1, 0≤y≤1, and x+y≤1). For example, the gate semiconductor layer 152 may include at least one from among AlN, GaN, InN, InGaN, AlGaN, AlInN, and AlInGaN. The gate semiconductor layer 152 may include a material having a different energy band gap from that of the barrier layer 136. For example, the gate semiconductor layer 152 may include GaN, and the barrier layer 136 may include AlGaN. The gate semiconductor layer 152 may be doped with predetermined impurities. In this case, the impurities doped into the gate semiconductor layer 152 may be p-type dopants capable of providing a hole. For example, the gate semiconductor layer 152 may include GaN doped with the p-type impurities. That is, the gate semiconductor layer 152 may be made of a p-GaN layer. However, embodiments of the present disclosure are not limited thereto, and the gate semiconductor layer 152 may be a p-AlGaN layer. The impurities doped into the gate semiconductor layer 152 may be magnesium (Mg). The gate semiconductor layer 152 may be formed of a single layer or multiple layers.

A depletion region DPR may be formed within the channel layer 132 by the gate semiconductor layer 152. The depletion region DPR may be disposed within the drift region DTR, and may have a narrower width than a width of the drift region DTR. Because the gate semiconductor layer 152 that has a different energy band gap from that of the barrier layer 136 is disposed above the barrier layer 136, a level of an energy band of a portion of the barrier layer 136 that overlaps the gate semiconductor layer 152 may increase. Accordingly, the depletion region DPR may be formed at a region of the channel layer 132 that overlaps with the gate semiconductor layer 152. The depletion region DPR may be a region in which the two-dimensional electron gas 134 is not formed or has an electron concentration lower than an electron concentration of the remaining region among a channel path of the channel layer 132. In other words, the depletion region DPR may mean a region where a flow of the two-dimensional electron gas 134 is cut off within the drift region DTR. As the depletion region DPR occurs, an electric current may not flow between the source electrode 173 and the drain electrode 175, and the channel path may be cut off. Accordingly, the semiconductor device according to the embodiment may have a normally off characteristic.

That is, the semiconductor device according to the embodiment may be a normally-off high electron mobility transistor (HEMT). As shown in FIG. 1, in a normal state in which a voltage is not applied to the gate electrode 155, the depletion region DPR may exist and the semiconductor device according to the embodiment may be in an off state. As shown in FIG. 2, if a voltage higher than or equal to a threshold voltage is applied to the gate electrode 155, the depletion region DPR may disappear, and the two-dimensional electron gas 134 may be connected without being cut off within the drift region DTR. That is, the two-dimensional electron gas 134 may be formed over an entire channel path between the source electrode 173 and the drain electrode 175, and the semiconductor device according to the embodiment may be in an on state. In summary, the semiconductor device according to the embodiment may include semiconductor layers with different electrical polarization characteristics, and the semiconductor layer with a relatively large polarization rate may induce the two-dimensional electron gas in another semiconductor layer heterojunctioned with the semiconductor layer with the relatively large polarization rate. The two-dimensional electron gas 134 may be used as a channel between the source electrode 173 and the drain electrode 175, and continuation or interruption of the flow of the two-dimensional electron gas 134 may be controlled by a bias voltage applied to the gate electrode 155. In a gate-off state, the flow of the two-dimensional electron gas 134 may be cut off, so that an electric current does not flow between the source electrode 173 and the drain electrode 175. As the flow of the two-dimensional electron gas 134 continues in a gate-on state, an electric current may flow between the source electrode 173 and the drain electrode 175.

The upper superlattice layer 128 may be disposed between the gate semiconductor layer 152 and the barrier layer 136. Specifically, the upper superlattice layer 128 may be disposed at an interface between the gate semiconductor layer 152 and the barrier layer 136. An upper surface of the upper superlattice layer 128 may be in contact with the gate semiconductor layer 152, and a lower surface of the upper superlattice layer 128 may be in contact with the barrier layer 136. A width of the upper superlattice layer 128 may be smaller than a width of the barrier layer 136. The width of the upper superlattice layer 128 may be substantially the same as a width of the gate semiconductor layer 152. In other words, the upper superlattice layer 128 may completely overlap with the gate semiconductor layer 152 in a vertical direction, and the upper surface of the upper superlattice layer 128 may be covered by the gate semiconductor layer 152. The upper superlattice layer 128 may have substantially the same planar shape as that of the gate semiconductor layer 152. The upper superlattice layer 128 may be disposed between the source electrode 173 and the drain electrode 175. The upper superlattice layer 128 may be spaced apart from the source electrode 173 and the drain electrode 175. The upper superlattice layer 128 may be disposed closer to the source electrode 173 than the drain electrode 175.

The upper superlattice layer 128 may include a structure in which a plurality of layers including different materials are alternately stacked. In an embodiment, the upper superlattice layer 128 may include a structure in which two layers including different materials are alternately stacked. However, the number of alternately stacked layers is not limited. For example, the upper superlattice layer 128 may have a structure in which three or more layers including different materials are alternately stacked. For example, each layer included in the upper superlattice layer 128 may include at least one material selected from nitride including at least one from among Group III-V materials (e.g., Al, Ga, In, and B). Each layer included in the upper superlattice layer 128 may be AlₓIn_{y}Ga_{1-x-y}N (0≤x≤1, 0≤y≤1, and x+y≤1). However, a ratio of Al, In, and Ga included in each of the plurality of layers may be different in each layer. In an embodiment, the upper superlattice layer 128 may further include other layers in addition to a plurality of AlGaN layers and GaN layers alternately stacked. For example, the upper superlattice layer 128 may include an AlGaN layer and a GaN layer alternately stacked. Alternatively, in addition to the AlGaN layer and the GaN layer alternately stacked, the upper superlattice layer 128 may further include one or more layers that includes a material different from a material of the AlGaN layers and the GaN layers alternately stacked or includes a different material composition ratio (e.g., an Al composition ratio and/or a Ga composition ratio) from a material composition ratio of the AlGaN layer and the GaN layer alternately stacked. The layers may be disposed at uppermost or lowermost portions of the upper superlattice layer 128, or may be disposed between the AlGaN layer and the GaN layer alternately stacked.

If the upper superlattice layer 128 has a structure in which two layers including different materials are alternately stacked, a first layer of the two layers may include AlGaN, and a second layer of the two layers may include GaN. That is, the upper superlattice layer 128 may have a structure in which the first layer including AlGaN and the second layer including GaN are alternately stacked. In an embodiment, the upper superlattice layer 128 may include two or more AlGaN layers and two or more GaN layers. The upper superlattice layer 128 may have a structure in which a plurality of AlGaN layers and a plurality of GaN layers are alternately stacked. In this case, a composition ratio of Al included in the plurality of AlGaN layers may be different in each layer.

The upper superlattice layer 128 may be doped by predetermined impurities. For example, the upper superlattice layer 128 may be doped with p-type dopants. That is, the upper superlattice layer may include a p-type semiconductor doped by the p-type dopants. For example, the upper superlattice layer 128 may have a structure in which AlGaN layers doped with the p-type dopant and GaN layers doped with the p-type dopant are alternately stacked. That is, the upper superlattice layer 128 may have a structure in which p-AlGaN layers and p-GaN layers are alternately stacked. In an embodiment, the upper superlattice layer 128 may be doped with a Group 2 element. For example, the upper superlattice layer 128 may be doped with Mg. However, a type of the dopant is not limited, and the upper superlattice layer 128 may be doped with various elements. In an embodiment, a doping concentration of the upper superlattice layer 128 may be greater than a doping concentration of the gate semiconductor layer 152. In an embodiment, the upper superlattice layer 128 may have a doping concentration that increases towards the barrier layer 136. In another embodiment, the doping concentration of the upper superlattice layer 128 may be equal to the doping concentration of the gate semiconductor layer 152.

The buffer layer 122, the lower superlattice layer 124, the high resistance layer 126, the channel layer 132, the barrier layer 136, and the gate semiconductor layer 152 described above may be sequentially stacked on the substrate 110. In the semiconductor device according to an embodiment, at least one from among the buffer layer 122, the lower superlattice layer 124, the high resistance layer 126, the channel layer 132, the barrier layer 136, and the gate semiconductor layer 152 may be omitted. The buffer layer 122, the lower superlattice layer 124, the high resistance layer 126, the channel layer 132, the barrier layer 136, and the gate semiconductor layer 152 may be made of the same semiconductor material as each other, and a material composition ratio of each layer may be different in consideration of a role of each layer, a performance required for the semiconductor device, or the like.

The source electrode 173 and the drain electrode 175 may be disposed on the channel layer 132. The source electrode 173 and the drain electrode 175 may be spaced apart from each other, and the gate electrode 155 and the gate semiconductor layer 152 may be disposed between the source electrode 173 and the drain electrode 175. The gate electrode 155 and the gate semiconductor layer 152 may be spaced apart from the source electrode 173 and the drain electrode 175. The source electrode 173 may be electrically connected to the channel layer 132 at one side of the gate electrode 155. The drain electrode 175 may be electrically connected to the channel layer 132 at the other side of the gate electrode 155. The source electrode 173 and the drain electrode 175 may be disposed outside the drift region DTR of the channel layer 132. An interface between the source electrode 173 and the channel layer 132 may be an edge of one side of the drift region DTR. Likewise, an interface between the drain electrode 175 and the channel layer 132 may be an edge of the other side of the drift region DTR.

The source electrode 173 and the drain electrode 175 may include a conductive material. For example, the source electrode 173 and the drain electrode 175 may include a metal, a metal alloy, conductive metal nitride, metal silicide, a doped semiconductor material, conductive metal oxide, conductive metal oxynitride, or the like. For example, the source electrode 173 and the drain electrode 175 may include titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TIC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or a combination thereof, but embodiments of the present disclosure are not limited thereto. The source electrode 173 and the drain electrode 175 may be formed of a single layer or multiple layers. The source electrode 173 and the drain electrode 175 may be in an ohmic contact with the channel layer 132. A region in contact with the source electrode 173 and the drain electrode 175 within the channel layer 132 may be doped at a relatively high concentration compared with another region.

The semiconductor device according to the embodiment may include a first protective layer 140 covering upper surfaces of the barrier layer 136 and the gate electrode 155. The first protective layer 140 may cover side surfaces of the upper superlattice layer 128, the gate semiconductor layer 152, and the gate electrode 155. The first protective layer 140 may cover a portion of a side surface of the source electrode 173 and a portion of a side surface of the drain electrode 175. A lower portion surface of the first protective layer 140 may be in contact with the barrier layer 136, the gate electrode 155, and the gate semiconductor layer 152.

The first protective layer 140 may include an insulating material. For example, the first protective layer 140 may include a material such as SiO₂, SiN, SiON, Al₂O₃, or the like. The first protective layer 140 may be formed of a single layer or multiple layers. According to embodiments, the first protective layer 140 may include a first lower protective layer and a second upper protective layer. In an embodiment, the first protective layer 140 may include three or more layers.

In general, based on a configuration of a circuit or a device that includes the semiconductor device, it may be required to manufacture the semiconductor device having a threshold voltage with a target size. In a semiconductor device having a structure similar to that of the semiconductor device described based on FIG. 1 and FIG. 2, a threshold voltage may vary depending on a doping concentration of the gate semiconductor layer 152. For example, the threshold voltage of the semiconductor device may have a larger value as the doping concentration of the gate semiconductor layer 152 increases. For example, if the gate semiconductor layer 152 is a p-GaN layer doped with Mg, the threshold voltage of the semiconductor device may increase as a doping concentration of the p-GaN layer included in the gate semiconductor layer 152 increases.

If the GaN layer is doped with Mg, a doping yield (or a doping efficiency) may be very small. For example, if the GaN layer is doped with Mg, the doping yield may be about 1%. If Mg is excessively doped into the gate semiconductor layer 152 including the p-GaN layer in order to increase the threshold voltage, Mg atoms that do not contribute to the doping may act as a defect inside the film (or the layer). In addition, Mg ions that do not contribute to the doping may move to an interface between the channel layer 132 and barrier layer 136 by diffusion to prevent formation of the two-dimensional electron gas 134.

In the same structure as the semiconductor device described with reference to FIG. 1 and FIG. 2, an AlGaN/GaN superlattice layer included in the upper superlattice layer 128 may have a higher doping yield than a doping yield of the GaN layer included in the gate semiconductor layer 152. For example, the doping yield of the AlGaN/GaN superlattice layer included in the upper superlattice layer 128 may be about 5% to about 10%.

As described with reference to FIG. 1 and FIG. 2, if the AlGaN/GaN superlattice layer is disposed at the interface between the gate semiconductor layer 152 and the barrier layer 136, the doping yield of the semiconductor device may increase. In this case, the semiconductor device that has a target threshold voltage and minimizes the defect inside the film or interference with the formation of the two-dimensional electron gas 134 that is caused by over-doping of Mg, may be manufactured.

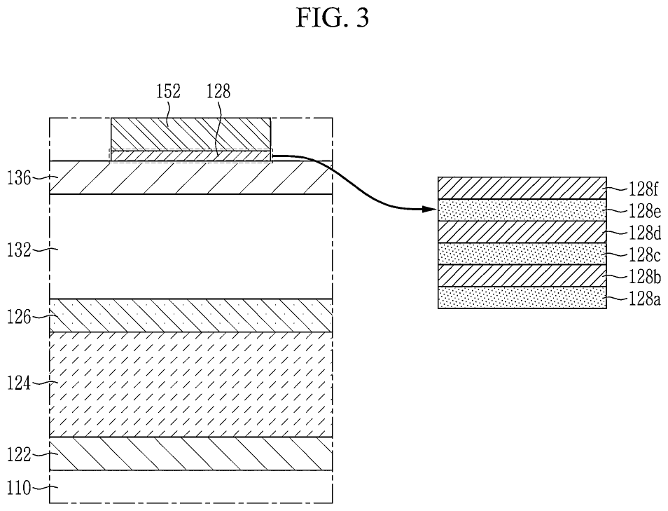

FIG. 3 is an enlarged cross-sectional view of a region A of FIG. 1. Specifically, FIG. 3 is a view for describing the upper superlattice layer 128 of FIG. 1 in detail.

The upper superlattice layer 128 may have the structure in which the plurality of AlGaN layers and the plurality of GaN layers are alternately stacked. Referring to FIG. 3, the upper superlattice layer 128 may have a structure in which a first layer 128a, a second layer 128b, a third layer 128c, a fourth layer a128d, a fifth layer 128e, and a sixth layer 128f are sequentially stacked. In FIG. 3, an odd layer and an even layer may include different materials from each other. For example, the first layer 128a, the third layer 128c, and the fifth layer 128e may be respective AlGaN layers, and the second layer 128b, the fourth layer 128d, and the sixth layer 128f may be respective GaN layers. As shown in FIG. 3, the upper superlattice layer 128 may have a structure in which the AlGaN layer and the GaN layer are alternately stacked three times, respectively. However, the number of layers included in the upper superlattice layer 128 is not limited. In another embodiment, the upper superlattice layer 128 may have a structure in which one AlGaN layer and one GaN layer are stacked. In another embodiment, the upper superlattice layer 128 may have a structure in which the AlGaN layer and the GaN layer are alternately stacked five times, respectively.

A lowermost end layer (e.g., the first layer 128a of FIG. 3) of the upper superlattice layer 128 may include the same material as a material of the barrier layer 136. For example, if the barrier layer 136 is an AlGaN layer in FIG. 3, the first layer 128a may be an AlGaN layer. An uppermost end layer (e.g., the sixth layer 128f of FIG. 3) of the upper superlattice layer 128 may include the same material as a material of the gate semiconductor layer 152. For example, in FIG. 3, if the gate semiconductor layer 152 is a GaN layer, the sixth layer 128f may be a GaN layer. That is, if the barrier layer 136 is an AlGaN layer and the gate semiconductor layer 152 is a GaN layer, odd layers of the upper superlattice layer 128 may be respective AlGaN layers, and even layers of the upper superlattice layer 128 may be respective GaN layers. However, embodiments of the present disclosure are not limited thereto, and a lowermost end layer of the upper superlattice layer 128 may include a material different from a material of the barrier layer 136, and an uppermost end layer of the upper superlattice layer 128 may include a material different from a material of the gate semiconductor layer 152. For example, if the barrier layer 136 is an AlGaN layer and the gate semiconductor layer 152 is a GaN layer, the odd layers of the upper superlattice layer 128 may be respective GaN layers, and the even layers of the upper superlattice layer 128 may be respective AlGaN layers.

The upper superlattice layer 128 and the barrier layer 136 may include AlGaN layers. In an embodiment, the AlGaN layer included in the upper superlattice layer 128 may have a lower Al composition ratio compared with a composition ratio of Al included in the barrier layer 136. For example, an Al composition ratio of the AlGaN layer included in the barrier layer 136 may be about 10 at % to about 20 at %.

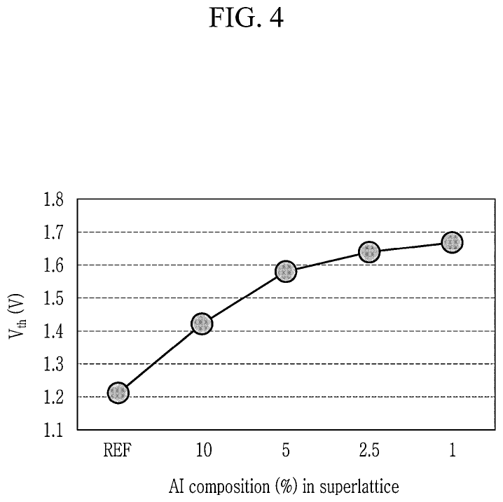

FIG. 4 is a view for describing a threshold voltage of the semiconductor device according to a composition ratio of aluminum inside the superlattice layer. In FIG. 4, a horizontal axis may represent the Al composition ratio in the AlGaN/GaN superlattice layer included in the upper superlattice layer 128, and a vertical axis may represent the threshold voltage Vth of the semiconductor device. In FIG. 4, a reference composition ratio REF may represent the Al composition ratio in the AlGaN layer included in the barrier layer 136. For example, the reference composition ratio REF may be 13 at %.

Referring to FIG. 4, the threshold voltage Vth of the semiconductor device may gradually increase as the Al composition ratio in the AlGaN/GaN superlattice layer included in the upper superlattice layer 128 decreases. The threshold voltage of the semiconductor device may be saturated in a section where the Al composition ratio in the AlGaN/GaN superlattice layer is 5 at % to 1 at %.

If the Al composition ratio in the AlGaN/GaN superlattice layer is excessively low (e.g., if the Al composition ratio in the AlGaN/GaN superlattice layer is less than 1 at %), the AlGaN/GaN superlattice layer may be substantially the same layer as a GaN single layer. In this case, an effect of increasing a doping yield of Mg by the AlGaN/GaN superlattice layer may be significantly reduced. Therefore, it may be necessary to select an appropriate Al composition ratio within a target threshold voltage range Vth.

In an embodiment, an Al composition ratio of the AlGaN layer included in the upper superlattice layer 128 may be about 1 at % to about 5 at %. As another example, the Al composition ratio of the AlGaN layer included in the upper superlattice layer 128 may be about 1 at % to about 2.5 at %. As another example, the Al composition ratio of the AlGaN layer included in the upper superlattice layer 128 may be about 2.5 at % to about 5 at %.

Referring back to FIG. 3, if the upper superlattice layer 128 includes a plurality of AlGaN layers, the plurality of AlGaN layers included in the upper superlattice layer 128 may have different Al composition ratios from each other. However, embodiments of the present disclosure are not limited thereto, and all of the plurality of AlGaN layers included in the upper superlattice layer 128 may have substantially the same Al composition ratio as each other. Alternatively, some layers among the plurality of AlGaN layers included in the upper superlattice layer 128 may have the same Al composition ratio, and other layers among the plurality of AlGaN layers included in the upper superlattice layer 128 may have different Al composition ratios. In some embodiments, the Al composition ratio of the AlGaN layer closest to the barrier layer 136 among the plurality of AlGaN layers may be the lowest. For example, referring to FIG. 3, in the upper superlattice layer 128, the first layer 128a, the third layer 128c, and the fifth layer 128e may each be an AlGaN layer. In this case, the first layer 128a among the first layer 128a, the third layer 128c, and the fifth layer 128e may be closest to the barrier layer 136, so that the first layer 128a has a lower Al composition ratio compared with Al composition ratios of the third layer 128c and the fifth layer 128e. For example, the Al composition ratio of the first layer 128a may be about 1 at % to about 5 at %.

The Al composition ratio within the AlGaN layer included in the upper superlattice layer 128 may gradually decrease as the upper superlattice layer 128 approaches the barrier layer 136. In other words, an uppermost layer among the AlGaN layers included in the upper superlattice layer 128 may have the highest Al composition ratio, and a lowermost layer among the AlGaN layers included in the upper superlattice layer 128 may have the lowest Al composition ratio. The Al composition ratio may gradually decrease from the uppermost layer of the upper superlattice layer 128 to the lowermost layer of the upper superlattice layer 128.

The Al composition ratio within the AlGaN layer included in the upper superlattice layer 128 may decrease step by step as the upper superlattice layer 128 approaches the barrier layer 136. For example, if the first layer 128a, the third layer 128c, and the fifth layer 128e are each AlGaN layers in the upper superlattice layer 128 of FIG. 3, the fifth layer 128e may have an Al composition ratio of 5 at %, the third layer 128c may have an Al composition ratio of 3 at %, and the first layer 128a may have an Al composition ratio of 1 at %. However, a difference in an Al composition ratio between the layers is not limited to 2 at %, and may be variously set.

The upper superlattice layer 128 may include the p-type semiconductor doped with the p-type dopant. For example, the upper superlattice layer 128 may have a structure in which AlGaN layers doped with the p-type dopant and GaN layers doped with the p-type dopant are alternately stacked. That is, the upper superlattice layer 128 may have a structure in which p-AlGaN layers and p-GaN layers are alternately stacked. In an embodiment, the upper superlattice layer 128 may be doped with Mg. In an embodiment, the p-AlGaN layer and the p-GaN layer included in the upper superlattice layer 128 may have a higher doping concentration compared with a doping concentration of the p-GaN layer included in the gate semiconductor layer 152. However, embodiments of the present disclosure are not limited thereto, and in another embodiment, the doping concentration of the upper superlattice layer 128 may be the same as the doping concentration of the gate semiconductor layer 152.

If the upper superlattice layer 128 includes a plurality of AlGaN layers and a plurality of GaN layers as shown in FIG. 3, the layers included in the upper superlattice layer 128 may have different doping concentrations. In an embodiment, the upper superlattice layer 128 may have a higher doping concentration since the upper superlattice layer 128 is adjacent to the barrier layer 136. Referring to FIG. 3, in the upper superlattice layer 128, the first layer 128a, the third layer 128c, and the fifth layer 128e may be p-AlGaN layers, and the second layer 128b, the fourth layer 128d, and the sixth layer 128f may be p-GaN layers. In this case, because the first layer 128a is closest to the barrier layer 136, the first layer 128a may have a higher doping concentration compared with doping concentrations of the second to sixth layers 128b-128f.

The upper superlattice layer 128 may have a very small thickness compared with the gate semiconductor layer 152. In an embodiment, the plurality of AlGaN layers and the plurality of GaN layers included in the upper superlattice layer 128 may have substantially the same thickness as each other. For example, a thickness of each of the first to sixth layers 128a to 128f in FIG. 3 may be greater than or equal to about 1 nm, and may be less than or equal to about 3 nm. For example, each of the first to sixth layers 128a-128f may have a thickness of about 1.5 nm.

An entire thickness of the upper superlattice layer 128 may be about 10% of a thickness of the gate semiconductor layer 152. In an embodiment, the entire thickness of the upper superlattice layer 128 may be determined according to thicknesses and the number of layers of each AlGaN layer and each GaN layer included in the upper superlattice layer 128. For example, the entire thickness of the upper superlattice layer 128 may be from about 3 nm to about 30 nm.

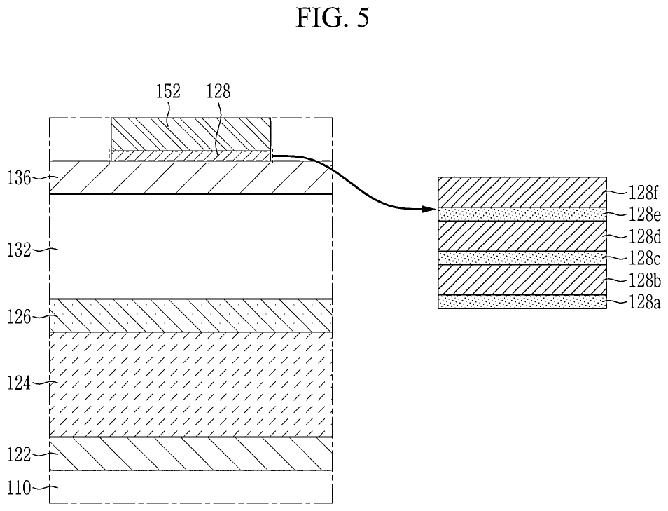

FIG. 5 is a view showing a semiconductor device according to an embodiment. Because the embodiment shown in FIG. 5 includes the same or similar components as the embodiment shown in FIGS. 1 to 3, a repeated description thereof may be omitted, and a difference between the embodiment shown in FIG. 5 and the embodiment shown in FIGS. 1 to 3 will be mainly described. In the embodiment shown in FIG. 5, thicknesses of AlGaN layers and GaN layers included in the upper superlattice layer 128 may be partially different from those of the previous embodiment.

Referring to FIG. 5, the upper superlattice layer 128 may include the first to sixth layers 128a-128f. In FIG. 5, the first layer 128a, the third layer 128c, and the fifth layer 128e may each be an AlGaN layer, and the second layer 128b, the fourth layer 128d, and the sixth layer 128f may each be a GaN layer. A thickness of each of the first to sixth layers 128a to 128f in FIG. 5 may be greater than or equal to about 1 nm, and may be less than or equal to about 3 nm. In an embodiment, a plurality of AlGaN layers and a plurality of GaN layers included in the upper superlattice layer 128 may have different thicknesses from each other. For example, as shown in FIG. 5, the AlGaN layers may have a smaller thickness compared with the GaN layers. However, the layers including the same material may have a same thickness as each other. For example, in FIG. 5, thicknesses of the first layer 128a, the third layer 128c, and the fifth layer 128e including the AlGaN layer may be the same. In FIG. 5, thicknesses of the second layer 128b, the fourth layer 128d, and the sixth layer 128f including the GaN layer may be the same. However, embodiments of the present disclosure are not limited thereto, and the layers included in the upper superlattice layer 128 may have different thicknesses. That is, in the upper superlattice layer 128, the layers including the same material may have different thicknesses from each other.

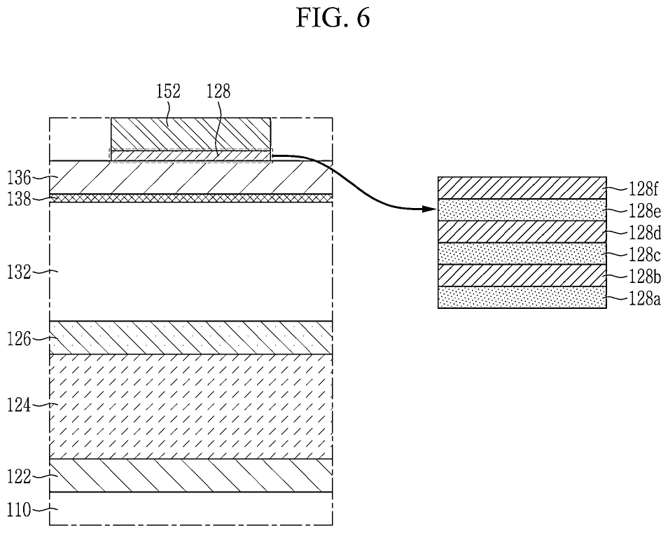

FIG. 6 is a view showing a semiconductor device according to an embodiment. Because the embodiment shown in FIG. 6 includes the same or similar components as the embodiment shown in FIGS. 1 to 3, a repeated description thereof may be omitted, and a difference between the embodiment shown in FIG. 6 and the embodiment shown in FIGS. 1 to 3 will be mainly described. In the embodiment shown in FIG. 6, a spacer layer 138 may be further included between the barrier layer 136 and the channel layer 132.

Referring to FIG. 6, the spacer layer 138 may be disposed between the channel layer 132 and the barrier layer 136. An upper surface of the spacer layer 138 may be in contact with a lower surface of the barrier layer 136. The lower surface of the spacer layer 138 may be in contact with the channel layer 132. The spacer layer 138 may have the same width as a width of the channel layer 132 and a width of the barrier layer 136.

The spacer layer 138 may include at least one material selected from nitride including at least one from among Group III-V materials (e.g., Al, Ga, In, and B). The spacer layer 138 may be AlₓIn_{y}Ga_{1-x-y}N (0≤x≤1, 0≤y≤1, and x+y≤1). For example, the spacer layer 138 may include at least one from among AlN, GaN, InN, InGaN, AlGaN, AlInN, and AlInGaN. In an embodiment, the spacer layer 138 may include a material having a different energy band gap from those of the channel layer 132 and the barrier layer 136. For example, the spacer layer 138 may include a material having a larger energy band gap than an energy band gap of a material included in each of the channel layer 132 and the barrier layer 136. For example, the channel layer 132 may include GaN, the barrier layer 136 may include AlGaN, and the spacer layer 138 may include AlN.

If the spacer layer 138, including a material with a larger energy band gap than that of a material included in the barrier layer 136, is disposed between the gate semiconductor layer 152 and the barrier layer 136, a density of the two-dimensional electron gas 134 formed inside the channel layer 132 may be increased compared with a case where the spacer layer 138 is not disposed. Accordingly, an electric characteristic of the semiconductor device may be improved compared with the case where the spacer layer 138 is not disposed.

In an embodiment, the spacer layer 138 may be very thin compared with thicknesses of the channel layer 132 and the barrier layer 136. If the spacer layer 138 is thick, crystallinity of the barrier layer 136 formed on the spacer layer 138 may be reduced due to a difference in a lattice constant between a material (e.g., AlN) included in the spacer layer 138 and a material (e.g., AlGaN) included in the barrier layer 136. Accordingly, the spacer layer 138 may have a very thin thickness compared with the thicknesses of the channel layer 132 and the barrier layer 136. For example, a thickness of the spacer layer 138 may be about 1 nm or less.

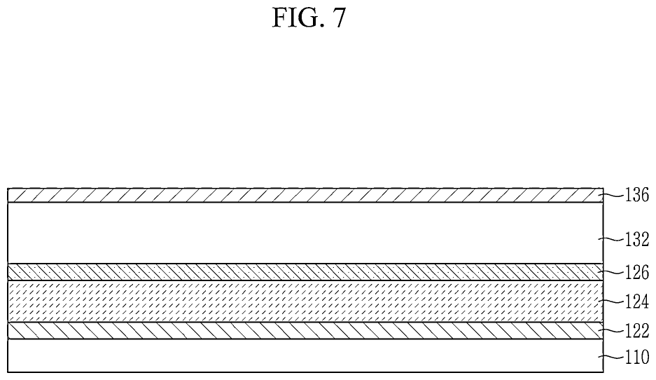

Next, a method for manufacturing the semiconductor device according to an embodiment will be described with reference to FIGS. 7 to 12.

FIGS. 7 to 12 are process cross-sectional views showing a process sequence for manufacturing the semiconductor device according to an embodiment.

First, as shown in FIG. 7, the buffer layer 122, the lower superlattice layer 124, the high resistance layer 126, the channel layer 132, and the barrier layer 136 may be sequentially formed on the substrate 110.

The substrate 110 may include a semiconductor material. For example, the substrate 110 may include sapphire, Si, SiC, AlN, GaN, or a combination thereof. The substrate 110 may be a silicon-on-insulator (SOI) substrate. However, a material of the substrate 110 is not limited thereto, and all commonly used substrates may be applied to the substrate 110.

Thereafter, the buffer layer 122, the lower superlattice layer 124, the high resistance layer 126, the channel layer 132, and the barrier layer 136 may be sequentially formed. For example, the buffer layer 122, the lower superlattice layer 124, the high resistance layer 126, the channel layer 132, and the barrier layer 136 may be sequentially formed using an epitaxial growth method. The buffer layer 122 may be first formed on the substrate 110, the lower superlattice layer 124 may be formed on the buffer layer 122, and the high resistance layer 126 may be formed on the lower superlattice layer 124. Next, the channel layer 132 may be formed on the high resistance layer 126, and the barrier layer 136 may be formed on the channel layer 132. According to embodiments, a seed layer may be further formed before the buffer layer 122 is formed on the substrate 110. In a final structure of the semiconductor device according to an embodiment, the seed layer may be disposed between the substrate 110 and the buffer layer 122. The seed layer may be a layer that serves as a seed for growing the buffer layer 122, and may be formed of a crystal lattice structure that becomes the seed of the buffer layer 122. The spacer layer 138 described with reference to FIG. 6 may be further formed between the channel layer 132 and the barrier layer 136.

The buffer layer 122, the lower superlattice layer 124, the high resistance layer 126, the channel layer 132, and the barrier layer 136 may be made of the same semiconductor material as each other. However, a material composition ratio of each layer may be different in consideration of a role of each layer, a performance required for the semiconductor device, or the like. The buffer layer 122, the lower superlattice layer 124, the high resistance layer 126, the channel layer 132, and the barrier layer 136 may include at least one material selected from nitride including at least one from among Group III-V materials (e.g., Al, Ga, In, and B). The buffer layer 122, the lower superlattice layer 124, the high resistance layer 126, the channel layer 132, and the barrier layer 136 may be AlₓIn_{y}Ga_{1-x-y}N (0≤x≤1, 0≤y≤1, and x+y≤1). For example, the buffer layer 122, the lower superlattice layer 124, the high resistance layer 126, the channel layer 132, and the barrier layer 136 may include at least one from among AlN, GaN, InN, InGaN, AlGaN, AlInN, and AlInGaN. The barrier layer 136 may include a material having a different energy band gap from that of the channel layer 132. The barrier layer 136 may have a higher energy band gap than that of the channel layer 132. A gate semiconductor material layer 152a may include a material having a different energy band gap from that of the barrier layer 136.

As an example, the substrate 110 may include Si, the buffer layer 122 may include GaN, and the lower superlattice layer 124 may have a structure in which a layer made of AlGaN and a layer made of GaN are repeatedly stacked. The high resistance layer 126 may include GaN, the channel layer 132 may include GaN, and the barrier layer 136 may include AlGaN. The lower superlattice layer 124, the channel layer 132, and the barrier layer 136 may or may not be doped with an impurity. The gate semiconductor material layer 152a may include GaN, and may be doped with impurities. The gate semiconductor material layer 152a may be doped with p-type impurities (e.g., magnesium (Mg)).

Because a lattice structure of Si and a lattice structure of GaN are different, it may not be easy to grow the channel layer 132 made of GaN directly on the substrate 110 made of Si. In the method of manufacturing the semiconductor device according to the embodiment, a lattice structure of the channel layer 132 may be stably formed by first forming the buffer layer 122, the lower superlattice layer 124, and the like on the substrate 110 and then forming the channel layer 132.

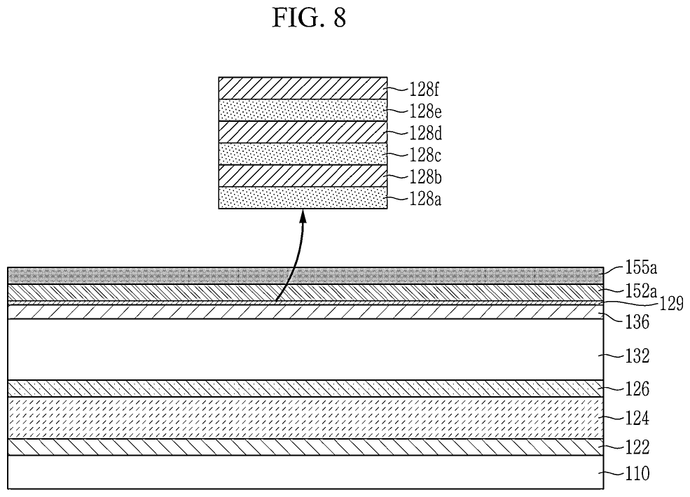

Subsequently, as shown in FIG. 8, an upper superlattice material layer 129, the gate semiconductor material layer 152a, and a gate electrode material layer 155a may be sequentially formed on the barrier layer 136. In the embodiment, the upper superlattice material layer 129 and the gate semiconductor material layer 152a may be continuously formed on the barrier layer 136 in the same process as a process for forming the barrier layer 136 after the barrier layer 136 is formed.

The upper superlattice material layer 129 and the gate semiconductor material layer 152a may be made of the same semiconductor material as a material of the buffer layer 122, the lower superlattice layer 124, the high resistance layer 126, the channel layer 132, and the barrier layer 136 described above. However, the upper superlattice material layer 129 and the gate semiconductor material layer 152a may have a different material composition ratio from the material composition ratios of the buffer layer 122, the lower superlattice layer 124, the high resistance layer 126, and the channel layer 132 described above

The upper superlattice material layer 129 and the gate semiconductor material layer 152a may be AlₓIn_{y}Ga_{1-x-y}N (0≤x≤1, 0≤y≤1, and x+y≤1). For example, the gate semiconductor material layer 152a may include at least one from among AlN, GaN, InN, InGaN, AlGaN, AlInN, and AlInGaN. The upper superlattice material layer 129 may include at least two from among AlN, GaN, InN, InGaN, AlGaN, AlInN, and AlInGaN. The upper superlattice material layer 129 may have a structure in which two materials selected from among AlN, GaN, InN, InGaN, AlGaN, AlInN, and AlInGaN are alternately stacked. For example, the upper superlattice material layer 129 may have a structure in which AlGaN and GaN are alternately stacked.

The gate semiconductor material layer 152a may include a material having a different energy band gap from that of the barrier layer 136. For example, the gate semiconductor material layer 152a may include GaN, and may be doped with impurities. The gate semiconductor material layer 152a may be doped with p-type impurities (e.g., magnesium (Mg)).

The upper superlattice material layer 129 may be formed by alternately stacking two or more layers including different materials. In this case, a composition ratio of the material included in each layer may be adjusted by adjusting composition or amounts of sources provided. Referring to FIG. 8, the upper super lattice material layer 129 may be formed by sequentially stacking the first layer 128a to the sixth layer 128f within the same process. In this case, the first layer 128a to the sixth layer 128f may be sequentially formed in the same process using an epitaxial growth method. Although six layers are shown in FIG. 8, the number of the layers included in the upper superlattice material layer 129 is not limited. The upper superlattice material layer 129 may be doped with p-type impurities (e.g., magnesium (Mg)). The upper superlattice material layer 129 may have a higher doping concentration compared with a doping concentration of the gate semiconductor material layer 152a. However, embodiments of the present disclosure are not limited thereto, and in another embodiment, the doping concentration of the upper superlattice material layer 129 may be the same as the doping concentration of the gate semiconductor material layer 152a. A thickness of each layer included in the upper superlattice material layer 129 may be about 1 nm to about 3 nm.

In an embodiment, a p-AlGaN layer may be formed in odd layers (e.g., the first layer 128a, the third layer 128c, and the fifth layer 128e) of the upper superlattice material layer 129, and a p-GaN layer may be formed in even layers (e.g., the second layer 128b, the fourth layer 128d, and the sixth layer 128f) of the upper superlattice material layer 129.

Referring to FIG. 8, the gate electrode material layer 155a may be formed on the gate semiconductor material layer 152a. The gate semiconductor material layer 152a may be disposed between the upper superlattice material layer 129 and the gate electrode material layer 155a.

The gate electrode material layer 155a may be formed using a deposition process. For example, the gate electrode material layer 155a may be formed using at least one from among a physical vapor deposition (PVD) technology, a thermal chemical vapor deposition (CVD) technology, a low pressure-chemical vapor deposition (LP-CVD) technology, a plasma enhanced chemical vapor deposition (PE-CVD) technology, and an atomic layer deposition (ALD) technology, but embodiments of the present disclosure are not limited thereto.

The gate electrode material layer 155a may include a conductive material. For example, the gate electrode material layer 155a may include a metal, a metal alloy, conductive metal nitride, metal silicide, a doped semiconductor material, conductive metal oxide, conductive metal oxynitride, or the like. For example, the gate electrode material layer 155a may include titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TIC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or a combination thereof, but embodiments of the present disclosure are not limited thereto. The gate electrode material layer 155a may be formed of a single layer or multiple layers.

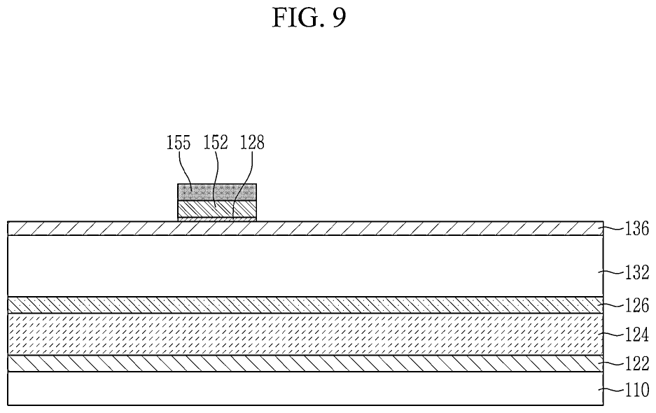

With reference to FIG. 9, the gate electrode material layer 155a, the gate semiconductor material layer 152a, and the upper superlattice material layer 129 may be patterned using photo and etching processes to form the gate electrode 155, the gate semiconductor layer 152, and the upper superlattice layer 128.

For example, a hard mask layer and a photoresist layer may be sequentially formed on the gate electrode material layer 155a. A photoresist pattern may be formed by patterning the photoresist layer using the photo process. A hard mask pattern may be formed by etching the hard mask layer using the photoresist pattern as a mask. By continuously etching the gate electrode material layer 155a, the gate semiconductor material layer 152a, and the upper superlattice material layer 129 using the hard mask pattern as a mask, at least portions of the gate electrode material layer 155a, the gate semiconductor material layer 152a, and the upper superlattice material layer 129 may be removed. Accordingly, a remaining portion of the gate electrode material layer 155a may become the gate electrode 155. Additionally, a remaining portion of the gate semiconductor material layer 152a may become the gate semiconductor layer 152. Additionally, a remaining portion of the upper superlattice material layer 129 may become the upper superlattice layer 128. The gate semiconductor layer 152 may be disposed between the upper superlattice layer 128 and the gate electrode 155. The gate electrode 155 may be in an ohmic contact with the gate semiconductor layer 152.

By patterning the gate semiconductor material layer 152a, the gate electrode material layer 155a, and the upper superlattice material layer 129 using the same mask, the gate semiconductor layer 152, the gate electrode 155, and the upper superlattice layer 128 may have the same pattern. That is, the gate semiconductor layer 152, the gate electrode 155, and the upper superlattice layer 128 may have the same planar shape as each other. In a cross-sectional view, the gate semiconductor layer 152, the gate electrode 155, and the upper superlattice layer 128 may have the same width as each other. The gate semiconductor layer 152, the gate electrode 155, and the upper superlattice layer 128 may completely overlap in a vertical direction, and an upper portion surface of the gate semiconductor layer 152 may be entirely covered by the gate electrode 155.

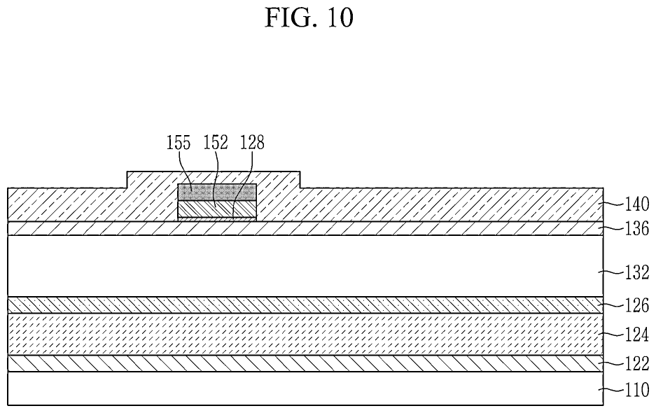

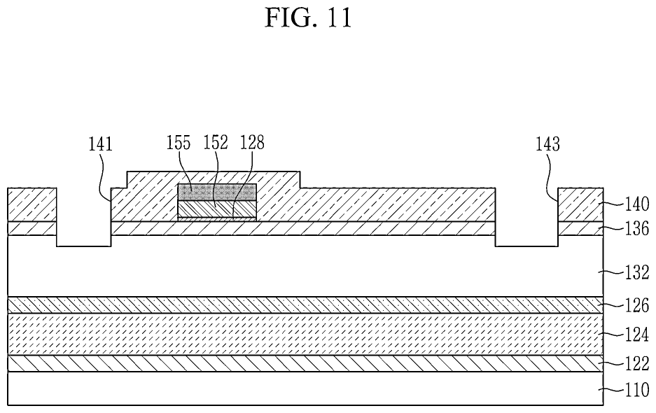

As shown in FIG. 10, the first protective layer 140 covering the gate electrode 155, a portion of an upper surface of the barrier layer 136, and side surfaces of the upper superlattice layer 128 and the gate semiconductor layer 152 may be formed. The first protective layer 140 may include an insulating material. For example, the first protective layer 140 may include a material such as SiO₂, SiN, SiON, Al₂O₃, or the like. The first protective layer 140 is shown as a single layer, but in an embodiment, the first protective layer 140 may be formed of multiple layers. In this case, the first protective layer 140 may be formed by sequentially depositing different materials. Alternatively, the first protective layer 140 made of several layers having different characteristics may be formed by varying a deposition condition using the same material. For example, a portion of the first protective layer 140 adjacent to the barrier layer 136 may be made of an insulating material having much better quality (e.g., insulation quality) than the quality of another portion. This is to prevent an electron forming a channel from being trapped within the channel layer 132 disposed below the barrier layer 136. The portion of the first protective layer 140 in contact with the barrier layer 136 may be made of SiO₂. Then, as shown in FIG. 11, a first trench 141 and a second trench 143 may be formed by patterning the first protective layer 140. In this case, some regions of the barrier layer 136 and the channel layer 132 may be patterned together.

For example, a photoresist pattern may be formed on the first protective layer 140, and the first protective layer 140, the barrier layer 136, and the channel layer 132 may be sequentially etched using the photoresist pattern photoresist pattern as a mask. In this case, the barrier layer 136 may be penetrated by the first trench 141 and the second trench 143, and an upper surface of the channel layer 132 may be recessed. The channel layer 132 may not be penetrated by the first trench 141 or the second trench 143. That is, a depth at which the upper surface of the channel layer 132 is recessed may be smaller than an entire thickness of the channel layer 132. In this case, the depth at which the upper surface of the channel layer 132 is recessed may be much smaller than the entire thickness of the channel layer 132. For example, the depth at which the upper surface of the channel layer 132 is recessed may be about 0% to about 30% of the entire thickness of the channel layer 132. Additionally, the depth at which the upper surface of the channel layer 132 is recessed may be smaller than a thickness of the barrier layer 136. However, embodiments of the present disclosure are not limited thereto, and the depth at which the upper surface of the channel layer 132 is recessed may be variously changed. A side surface of the barrier layer 136 may be exposed to the outside by the first trench 141 and the second trench 143, and an upper portion surface and a side surface of the channel layer 132 may be exposed to the outside by the first trench 141 and the second trench 143. The channel layer 132 may define bottom surfaces and sidewalls of the first trench 141 and the second trench 143, and the barrier layer 136 may define sidewalls of the first trench 141 and the second trench 143.

The first trench 141 and the second trench 143 may be spaced apart from each other. The first trench 141 and the second trench 143 may be disposed at both sides of the gate electrode 155. The first trench 141 may be disposed at one side of the gate electrode 155 to be spaced apart from the gate electrode 155. The second trench 143 may be disposed at the other side of the gate electrode 155 to be spaced apart from the gate electrode 155. A distance between the first trench 141 and the gate electrode 155 may be smaller than a distance between the second trench 143 and the gate electrode 155. Shapes such as widths, depths, and the like of the first trench 141 and the second trench 143 are shown to be similar, but embodiments of the present disclosure are not limited thereto. The shapes of the first trench 141 and the second trench 143 may be variously changed.

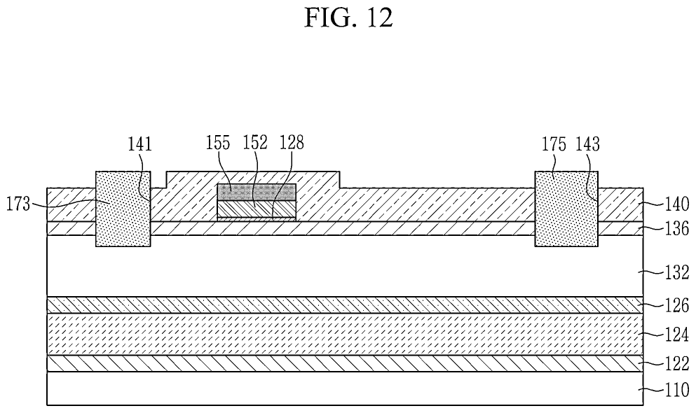

As shown in FIG. 12, a conductive material may be deposited on the first protective layer 140 at which the first trench 141 and the second trench 143 are formed, and the deposited conductive material may be patterned to form the source electrode 173 and the drain electrode 175.

The source electrode 173 and the drain electrode 175 may include a conductive material. For example, the source electrode 173 and the drain electrode 175 may include a metal, a metal alloy, conductive metal nitride, metal silicide, a doped semiconductor material, conductive metal oxide, conductive metal oxynitride, or the like. The source electrode 173 and the drain electrode 175 may be formed of a single layer or multiple layers. For example, a plurality of conductive layers including different materials may be stacked, and then the stacked layers may be patterned to form the source electrode 173 and the drain electrode 175. In this case, the plurality of conductive layers may be simultaneously or sequentially etched using one mask pattern. For example, the source electrode 173 and the drain electrode 175 may be formed by sequentially stacking Ti, Al, Ti, and TiN and then patterning the stacked layers. In this case, thicknesses of the four conductive layers constituting the source electrode 173 and the drain electrode 175 may be similar or different. For example, a layer made of Al may be relatively thicker than another layer.

The source electrode 173 may be formed to fill the inside of the first trench 141. Within the first trench 141, the source electrode 173 may be in contact with the channel layer 132 and the barrier layer 136. The source electrode 173 may be in contact with side surfaces of the channel layer 132 and the barrier layer 136. The source electrode 173 may cover the side surfaces of the channel layer 132 and the barrier layer 136. The source electrode 173 may be electrically connected to the channel layer 132 through the first trench 141.

The drain electrode 175 may be formed to fill the inside of the second trench 143. Within the second trench 143, the drain electrode 175 may be in contact with the channel layer 132 and the barrier layer 136. The drain electrode 175 may be in contact with side surfaces of the channel layer 132 and the barrier layer 136. The drain electrode 175 may cover the side surfaces of the channel layer 132 and the barrier layer 136. The drain electrode 175 may be electrically connected to the channel layer 132 through the second trench 143.

The source electrode 173 and the drain electrode 175 may be in an ohmic contact with the channel layer 132. A region in contact with the source electrode 173 and the drain electrode 175 within the channel layer 132 may be doped at a relatively high concentration compared with another region. For example, the channel layer 132 may be doped by an ion implant process, an annealing process, or the like. However, embodiments of the present disclosure are not limited thereto, and a doping process of the channel layer 132 may include various other processes. The doping process of the channel layer 132 may be performed before the source electrode 173 and the drain electrode 175 are formed. In an embodiment, the channel layer 132 may not be doped.

The two-dimensional electron gas 134 (refer to FIGS. 1-2) may be formed at a portion adjacent to the barrier layer 136 inside the channel layer 132. The two-dimensional electron gas 134 may be disposed at an interface between the channel layer 132 and the barrier layer 136. The two-dimensional electron gas 134 may be disposed at the drift region DTR between the source electrode 173 and the drain electrode 175. The depletion region DPR may be formed within the channel layer 132 by the gate semiconductor layer 152 having a different energy band gap from that of the barrier layer 136. Accordingly, the semiconductor device according to the embodiment may have a normally off characteristic. That is, the semiconductor device according to the embodiment may be a normally-off high electron mobility transistor (HEMT). In the gate-off state, the two-dimensional electron gas 134 may be disposed within the drift region DTR excluding the depletion region DPR of the channel layer 132. In the gate-on state, a flow of the two-dimensional electron gas 134 may continue within the depletion region DPR, so that the two-dimensional electron gas 134 is disposed entirely within the drift region DTR.

While non-limited embodiments of the present disclosure have been described above and illustrated in the drawings, it is to be understood that the present disclosure is not limited to these example embodiments, and, on the contrary, the present disclosure is intended to cover various modifications and equivalent arrangements included within the spirit and scope of the present disclosure.

What is claimed is:

1. A semiconductor device comprising:
a channel layer;
a barrier layer above the channel layer and comprising a material having an energy band gap that is different from an energy band gap of the channel layer;
a gate electrode above the barrier layer;
a gate semiconductor layer between the barrier layer and the gate electrode;
a source electrode at a first side of the gate electrode and on a first side surface of the channel layer and a first side surface of the barrier layer;
a drain electrode at a second side of the gate electrode, opposite to the first side, and on a second side surface of the channel layer and a second side surface of the barrier layer; and
a superlattice layer between the barrier layer and the gate semiconductor layer, the superlattice layer comprising at least one first layer comprising AlGaN and at least one second layer comprising GaN,
wherein the at least one first layer and the at least one second layer are alternately stacked.

2. The semiconductor device of claim 1, wherein the barrier layer comprises AlGaN, and the AlGaN in the barrier layer has an Al composition ratio different from an Al composition ratio of the AlGaN in the at least one first layer.

3. The semiconductor device of claim 2, wherein the Al composition ratio of the AlGaN in the at least one first layer is less than the Al composition ratio of the AlGaN in the barrier layer.

4. The semiconductor device of claim 1, wherein the at least one first layer has an Al composition ratio of 1 to 5 at %.

5. The semiconductor device of claim 1, wherein the at least one first layer is two or more first layers, and the at least one second layer is two or more second layers, and
wherein the two or more first layers have different Al composition ratios from each other.

6. The semiconductor device of claim 1, wherein the gate semiconductor layer and the superlattice layer are doped by p-type dopants, and the superlattice layer has a doping concentration equal to or greater than a doping concentration of the gate semiconductor layer.

7. The semiconductor device of claim 6, wherein the at least one first layer is two or more first layers, and the at least one second layer is two or more second layers, and
wherein the two or more first layers have different doping concentrations from each other, and the two or more second layers have different doping concentrations from each other.

8. The semiconductor device of claim 7, wherein the two or more first layers have an increasing doping concentration in an order of farthest to nearest layer among the two or more first layers to the barrier layer, and
wherein the two or more second layers have an increasing doping concentration in an order of farthest to nearest layer among the two or more second layers to the barrier layer.

9. The semiconductor device of claim 1, wherein each of the at least one first layer and the at least one second layer has a thickness greater than or equal to 1 nm and less than or equal to 3 nm.

10. The semiconductor device of claim 1, wherein the superlattice layer has a narrower width than a width of the barrier layer.

11. The semiconductor device of claim 10, wherein the superlattice layer has a width equal to a width of the gate semiconductor layer.

12. The semiconductor device of claim 6, wherein one of the at least one second layer is on one of the at least one first layer, the one of the at least one first layer is in contact with an upper surface of the barrier layer, and the one of the at least one second layer is in contact with a lower surface of the gate semiconductor layer.

13. A semiconductor device comprising:
a substrate;
a buffer layer on the substrate;
a lower superlattice layer above the buffer layer;
a channel layer above the lower superlattice layer;
a barrier layer above the channel layer and comprising a material with an energy band gap that is higher than an energy band gap of the channel layer;
a spacer layer between the channel layer and the barrier layer and comprising a material with an energy band gap that is higher than the energy band gap of the barrier layer;
a gate electrode above the barrier layer;
a gate semiconductor layer between the barrier layer and the gate electrode;
a source electrode at a first side of the gate electrode and on a first side surface of the channel layer and a first side surface of the barrier layer;
a drain electrode at a second side of the gate electrode, opposite to the first side, and on a second side surface of the channel layer and a second side surface of the barrier layer; and
an upper superlattice layer between the barrier layer and the gate semiconductor layer, the upper superlattice layer comprising at least one first layer comprising AlGaN and at least one second layer comprising GaN,
wherein the at least one first layer and the at least one second layer are alternately stacked.

14. The semiconductor device of claim 13, wherein the barrier layer comprises AlGaN, and an Al composition ratio of the AlGaN in the at least one first layer is less than an Al composition ratio of the AlGaN in the barrier layer.

15. The semiconductor device of claim 13, wherein the gate semiconductor layer and the upper superlattice layer are doped by p-type dopants, and the upper superlattice layer has a doping concentration equal to or greater a doping concentration of the gate semiconductor layer.

16. The semiconductor device of claim 15, wherein the at least one first layer is two or more first layers, and the at least one second layer is two or more second layers,
wherein the two or more first layers have different doping concentrations from each other, and the two or more second layers have different doping concentrations from each other,
wherein the two or more first layers have an increasing doping concentration in an order of farthest to nearest layer among the two or more first layers to the barrier layer, and
wherein the two or more second layers have an increasing doping concentration in an order of farthest to nearest layer among the two or more second layers to the barrier layer.

17. A semiconductor device comprising:
a channel layer comprising GaN;
a barrier layer above the channel layer and comprising AlGaN;
a gate electrode above the barrier layer and comprising a metallic material;
a gate semiconductor layer between the barrier layer and the gate electrode and comprising GaN doped with p-type impurities;
a source electrode at a first side of the gate electrode and in contact with a first side surface of the channel layer and a first side surface of the barrier layer;
a drain electrode at a second side of the gate electrode, opposite to the first side, and in contact with a second side surface of the channel layer and a second side surface of the barrier layer; and a superlattice layer between the barrier layer and the gate semiconductor layer, the superlattice layer comprising at least one first layer comprising AlGaN and at least one second layer comprising GaN,
wherein the at least one first layer and the at least one second layer are alternately stacked.

18. The semiconductor device of claim 17, wherein the barrier layer comprises AlGaN, and an Al composition ratio of the AlGaN in the at least one first layer is less than an Al composition ratio of the AlGaN in the barrier layer.

19. The semiconductor device of claim 17, wherein the gate semiconductor layer and the superlattice layer are doped by p-type dopants, and the superlattice layer has a doping concentration equal to or greater than a doping concentration of the gate semiconductor layer.

20. The semiconductor device of claim 19, wherein the at least one first layer is two or more first layers, and the at least one second layer is two or more second layers,
wherein the two or more first layers have different doping concentrations from each other, and the two or more second layers have different doping concentrations from each other,
wherein the two or more first layers have an increasing doping concentration in an order of farthest to nearest layer among the two or more first layers to the barrier layer, and
wherein the two or more second layers have an increasing doping concentration in an order of farthest to nearest layer among the two or more second layers to the barrier layer.
